(19) United States
(12) Patent Application Publication
(10) Pub. No.: US 2017/0077132 A1
(43) Pub. Date: Mar. 16, 2017

(54) NON-VOLATILE MEMORY DEVICE AND METHOD FOR MANUFACTURING SAME

(71) Applicant: Kabushiki Kaisha Toshiba, Minato-ku (JP)

(72) Inventor: Hideki INOKUMA, Yokkaichi (JP)

(73) Assignee: Kabushiki Kaisha Toshiba, Minato-ku (JP)

(21) Appl. No.: 15/063,923

(22) Filed: Mar. 8, 2016

Related U.S. Application Data
(60) Provisional application No. 62/216,661, filed on Sep. 10, 2015.

(51) Int. Cl. H01L 27/115

(52) U.S. Cl. CPC H01L 27/11582; H01L 27/11556

(57) ABSTRACT

A non-volatile memory device comprises a first electrode, a second electrode stacked on the first electrode, a semiconductor layer extending in a first direction through the first electrode and the second electrode, charge storage parts respectively provided between the first electrode and the semiconductor layer and between the second electrode and the semiconductor layer, and a barrier body arranged with the first electrode and the second electrode in a second direction orthogonal to the first direction and extending in the first direction. A distance between the second electrode and the barrier body is wider in the second direction than a distance between the first electrode and the barrier body.

### CROSS-REFERENCE TO RELATED APPLICATIONS

This application is based upon and claims the benefit of priority from U.S. Provisional Patent Application 62/216,661 filed on Sep. 10, 2015; the entire contents of which are incorporated herein by reference.

### FIELD

Embodiments are generally related to a non-volatile memory device and a method for manufacturing the same.

### BACKGROUND

There is a non-volatile memory device comprising three-dimensionally arranged memory cell transistors in order to increase the memory capacity thereof. Such a memory device includes word lines through which the control biases are applied to respective memory cell transistors, and a contact region where the word lines are electrically connected to a drive circuit via contact plugs. The word lines are stacked vertically, and have end parts formed into stairs in the contact region to expose the upper surfaces thereof. Thereby, it becomes possible to access the stacked word lines via the contact plugs arranged two-dimensionally in the contact region. However, such a contact region may occupy a large area in the chip surface and may become an obstacle to further enlarging the memory capacity.

Furthermore, an insulating layer covering the end parts of the stacked word lines is embedded in the contact region and planarized to form interconnects thereon. The completely planarized surface, however, is difficult to obtain due to the dishing in CMP (Chemical Mechanical Polishing). Such a dishing may worsen the resolution of photolithography, and make it difficult to achieve the fine interconnects.

### BRIEF DESCRIPTION OF THE DRAWINGS

FIGS. 1A and 1B are schematic cross-sectional views showing a non-volatile memory device according to an embodiment;

FIGS. 2A to 5F are schematic views showing a manufacturing process of the non-volatile memory device according to the embodiment;

FIGS. 6A to 7K are schematic cross-sectional views showing a manufacturing process of the non-volatile memory device according to a variation of the embodiment;

FIGS. 8A to 8C are schematic cross-sectional views showing a manufacturing process of the non-volatile memory device according to another variation of the embodiment; and

FIGS. 9A to 9D are schematic cross-sectional views showing a manufacturing process of a non-volatile memory device according to a comparable example.

### DETAILED DESCRIPTION

According to an embodiment, a non-volatile memory device comprises a first electrode, a second electrode stacked on the first electrode, a semiconductor layer extending in a first direction through the first electrode and the second electrode, charge storage parts respectively provided between the first electrode and the semiconductor layer and between the second electrode and the semiconductor layer, and a barrier body arranged with the first electrode and the second electrode in a second direction orthogonal to the first direction and extending in the first direction. A distance between the second electrode and the barrier body is wider in the second direction than a distance between the first electrode and the barrier body.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

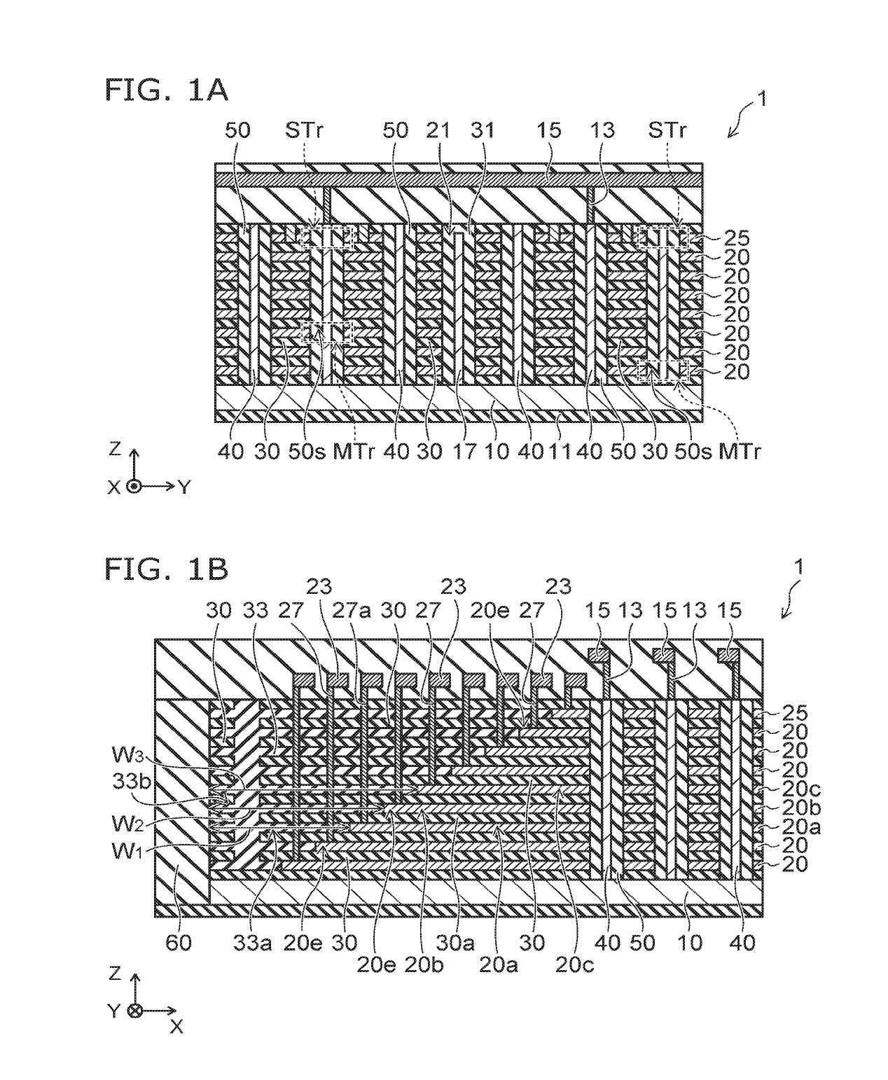

FIGS. 1A and 1B are schematic sectional views showing a non-volatile memory device 1 according to an embodiment. FIG. 1A is a schematic view showing a cross section taken along the Y-Z plane. FIG. 1B is a schematic view showing a cross section taken along the X-Z plane.

As shown in FIG. 1A, the non-volatile memory device 1 includes a conductive layer 10, a plurality of word lines 20, and a select gate 25. The word lines 20 are stacked on the conductive layer 10 via insulating layers 30. The select gate 25 is provided on the word lines 20 stacked in the Z-direction. The conductive layer 10 is provided on e.g. a silicon substrate, not shown, via an insulating layer 11.

The non-volatile memory device 1 further includes a semiconductor layer 40 and a memory layer 50. The semiconductor layer 40 extends through the word lines 20 and the select gate 25 in a first direction (hereinafter Z-direction). The memory layer 50 extends in the Z-direction along the semiconductor layer 40.

The non-volatile memory device 1 includes a memory cell transistor MTr at a portion where the semiconductor layer 40 extends through a word line 20. Furthermore, the non-volatile memory device 1 includes a select transistor STr in a portion where the semiconductor layer 40 extends through the select gate 25. The memory cell transistor MTr includes a charge storage part 50s. The charge storage part 50s is a part of the memory layer 50, and locates between the word line 20 and the semiconductor layer 40. The select transistor STr includes a gate insulating film. The gate insulating film is a part of the memory layer 50, and locates between the select gate 25 and the semiconductor layer 40.

For instance, the memory layer 50 has a structure in which a silicon oxide layer, a silicon nitride layer, and a silicon oxide layer are stacked sequentially in a direction from the word line 20 to the semiconductor layer 40. The memory layer 50 may include a metal oxide layer of e.g. hafnium oxide.

The non-volatile memory device 1 further includes a bit line 15 and a source contact body 17. The bit line 15 is electrically connected to the semiconductor layer 40 through a contact plug 13. The semiconductor layer 40 is connected at the upper end thereof to the contact plug 13. The semiconductor layer 40 is electrically connected at its lower end to the conductive layer 10. The source contact body 17 electrically connects the conductive layer 10 to a source line (not shown).

For instance, the source contact body 17 is provided inside a slit 21. The slit 21 is provided between the word lines 20 adjacent in the Y-direction. The source contact body 17 extends inside the slit 21 and is electrically connected at the lower end thereof to the conductive layer 10. Furthermore, the source contact body 17 is electrically insulated from the word line 20 by an insulating layer 31 covering the sidewall of the slit 21.

As shown in FIG. 1B, the plurality of word lines 20 each extend in the X-direction (second direction). The word lines 20 stacked in the Z-direction have end parts 20e formed into stairs. The word lines 20 include a word line 20a (first electrode), a word line 20b (second electrode), and a word line 20c (third electrode). The word line 20a is stacked on the word line 20b via an insulating layer 30a. The word line 20c is stacked on the word line 20b via other insulating layer 30.

The non-volatile memory device 1 further includes a gate interconnect 23, a contact plug 27, and a barrier body 60. The gate interconnect 23 is provided above a word line 20 and electrically connected to the word line 20 through the contact plug 27. The barrier body 60 is arranged with the word lines 20 in the X-direction.

The barrier body 60 is an insulator including, for example, silicon oxide, and extends in the Z-direction. For instance, the distance between the word line 20a and the barrier body 60 is denoted by W₁. The distance between the word line 20b and the barrier body 60 is denoted by W₂. The distance between the word line 20c and the barrier body 60 is denoted by W₃. Then, W₂ is wider than W₁, and W₃ is wider than W₂. That is, the end parts 20e of the word lines 20 are formed into the stairs. The contact plug 27 is connected to an end part 20e of the word line 20.

The non-volatile memory device 1 includes an insulating layer 33 between the barrier body 60 and each of the word lines 20. The insulating layer 33 extends in the X-direction. The insulating layer 30 between the word lines 20 stacked in the Z-direction extends toward the barrier body 60. The insulating layers 33 are stacked alternately with the insulating layers 30 between each of the word lines 20 and the barrier body 60. The contact plug 27 extends through the insulating layers 30 and the insulating layers 33 and is connected to the end part 20e of the word line 20.

For instance, an insulating layer 33a (first insulating layer) is provided between the word line 20a and the barrier body 60. The insulating layer 33a is in contact with the end of the word line 20a. An insulating layer 33b (second insulating layer) is provided between the word line 20b and the barrier body 60. The insulating layer 33b is in contact with the end of the word line 20b. An insulating layer 30a (third insulating layer) extends in the X-direction between the insulating layer 33a and the insulating layer 33b. The insulating layer 30a covers the surface of the word line 20a. The contact plug 27a extends through the insulating layer 33b and the insulating layer 30a and is in contact with the word line 20a.

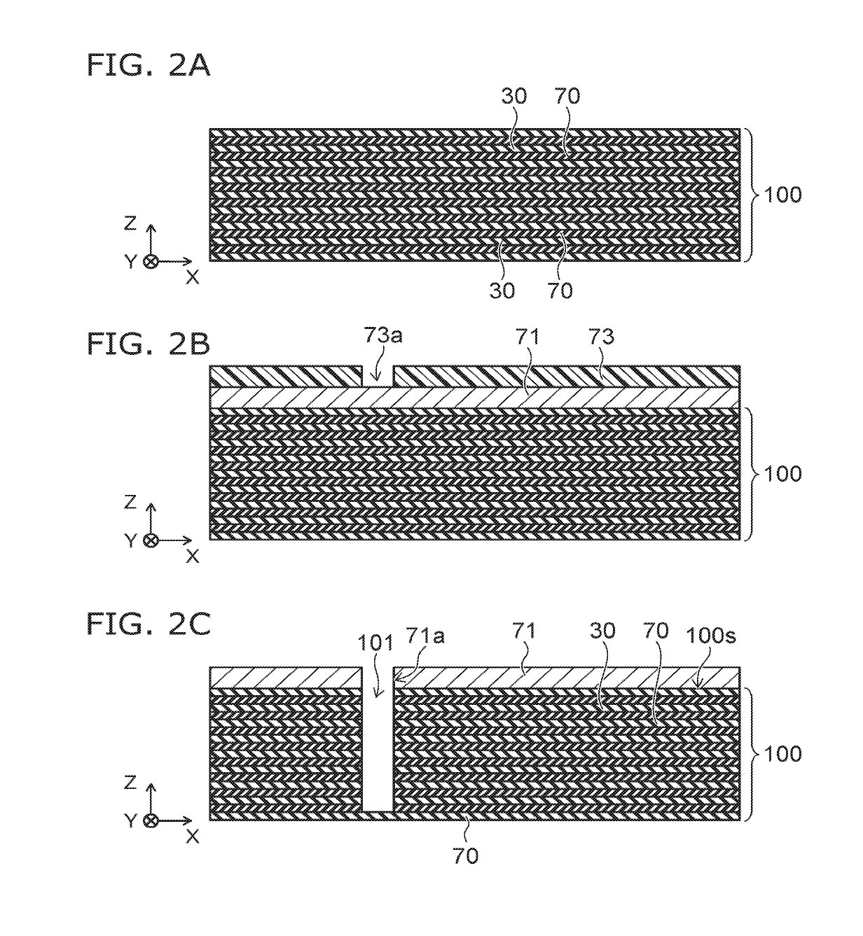

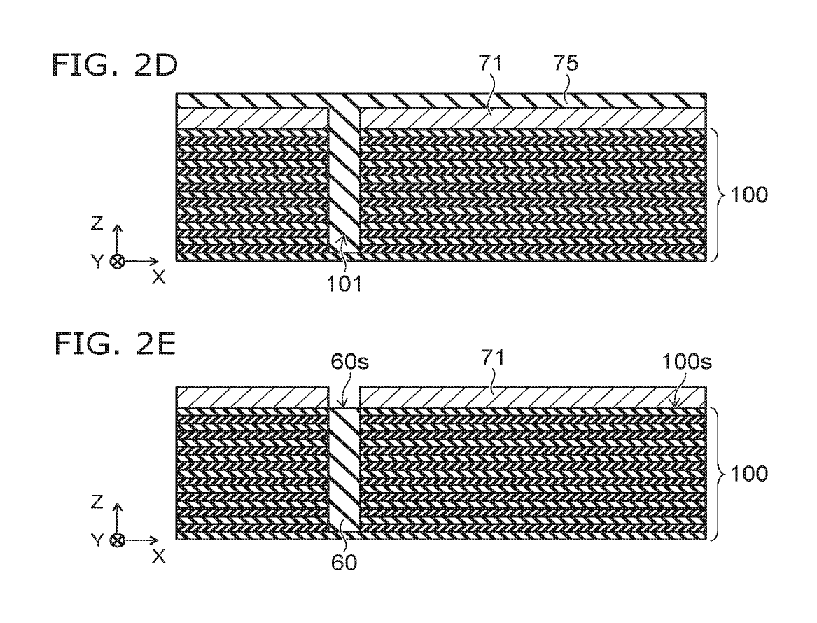

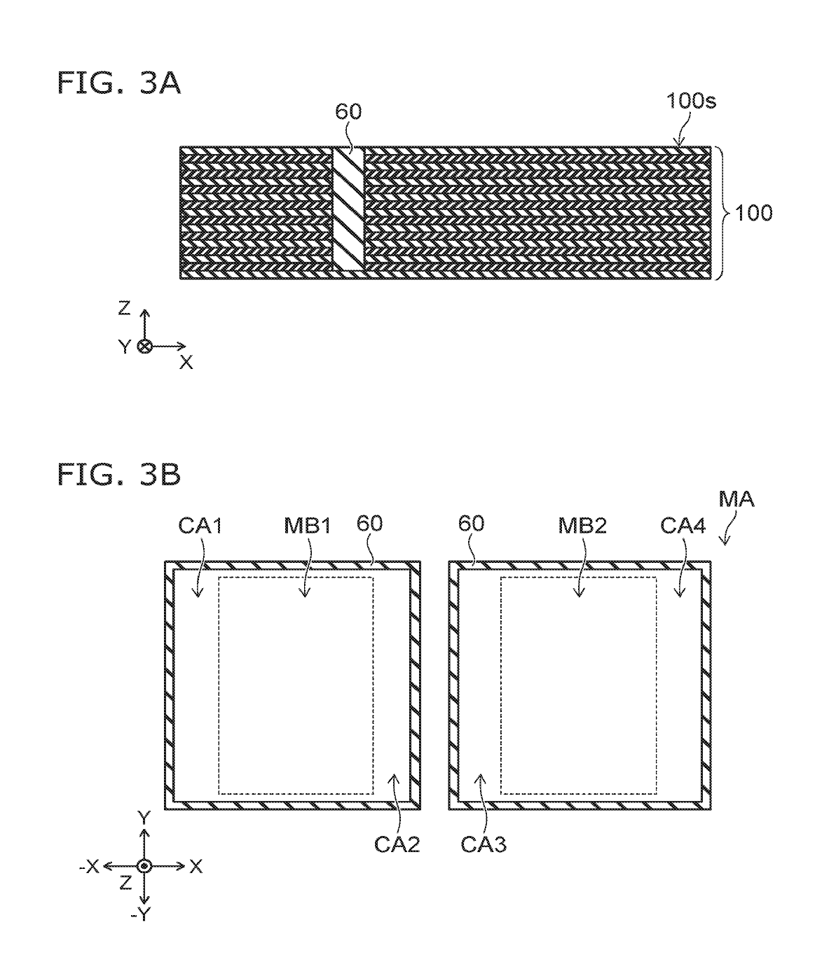

Next, a method for manufacturing the non-volatile memory device 1 according to the embodiment is described with reference to FIGS. 2A to 5F. FIGS. 2A to 5F are schematic views sequentially showing the manufacturing process of the non-volatile memory device 1 according to the embodiment. FIGS. 2A to 3A and FIGS. 4A to 5F are schematic sectional views of the stacked body 100 provided on the conductive layer 10. FIG. 3B is a top view thereof.

As shown in FIG. 2A, a stacked body 100 is formed, which includes a plurality of insulating layers 30 and a plurality of sacrificial layers 70. Each insulating layer 30 and each sacrificial layer 70 are stacked alternately in the Z-direction. The insulating layer 30 is a silicon oxide layer, for example. The sacrificial layer 70 is a silicon nitride layer, for example. The insulating layers 30 and the sacrificial layers 70 are formed, for example, by plasma enhanced chemical vapor deposition (PCVD).

As shown in FIG. 2B, a mask layer 71 is formed on the stacked body 100. The mask layer 71 is an amorphous silicon layer, for example. Further, a resist mask 73 is formed on the mask layer 71. The resist mask 73 has an opening 73a.

As shown in FIG. 2C, a trench 101 is formed in the stacked body 100. The trench 101 has a depth reaching the lowermost one of the plurality of sacrificial layers 70 from the upper surface 100s of the stacked body 100. The trench 101 is formed, for example, by RIE (Reactive Ion Etching) using the mask layer 71 as an etching mask. The mask layer 71 has an opening 71a formed by etching using the resist mask 73.

As shown in FIG. 2D, an insulating layer 75 is formed on the mask layer 71. The insulating layer 75 includes a portion covering the upper surface of the mask layer 71, and a portion embedded in the trench 101. The insulating layer 75 is, for example, a silicon oxide layer formed by PCVD. The insulating layer 75 may be a silicon oxide layer formed, for example, by low pressure chemical vapor deposition (LPCVD).

As shown in FIG. 2E, the insulating layer 75 is etched back to remove the portion formed on the mask layer 71 and the portion deposited above the trench 101 by dry etching, for example. Hereinafter, the portion of the insulating layer 75 embedded in the trench 101 is referred to as barrier body 60.

As shown in FIG. 3A, the mask layer 71 is removed. The mask layer 71 is selectively removed, for example, with an alkali-based etching liquid. The upper surface 60s of the barrier body 60 is formed, for example, so as to be located at the same level as the surface of the uppermost layer of the insulating layers 30.

FIG. 3B is a schematic plan view showing the upper surface 100s of the stacked body 100. As shown in FIG. 3B, the barrier body 60 is provided so as to surround the memory blocks MB1 and MB2 respectively in the memory region MA. The memory region MA includes a region where the memory blocks MB1 and MB2 is formed. The memory blocks MB1 and MB2 are arranged, for example, in the X-direction.

For example, contact regions CA1 and CA2 are provided on both sides of the memory block MB1. Contact regions CA3 and CA4 are provided on both sides of the memory block MB2. Each word line 20 is electrically connected to a gate interconnect 23 at the contact region CA1, CA2, CA3 or CA4. A barrier body 60 is formed so as to surround the memory block MB1 and the contact regions CA1 and CA2. Another barrier body 60 is formed so as to surround the memory block MB2 and the contact regions CA3 and CA4.

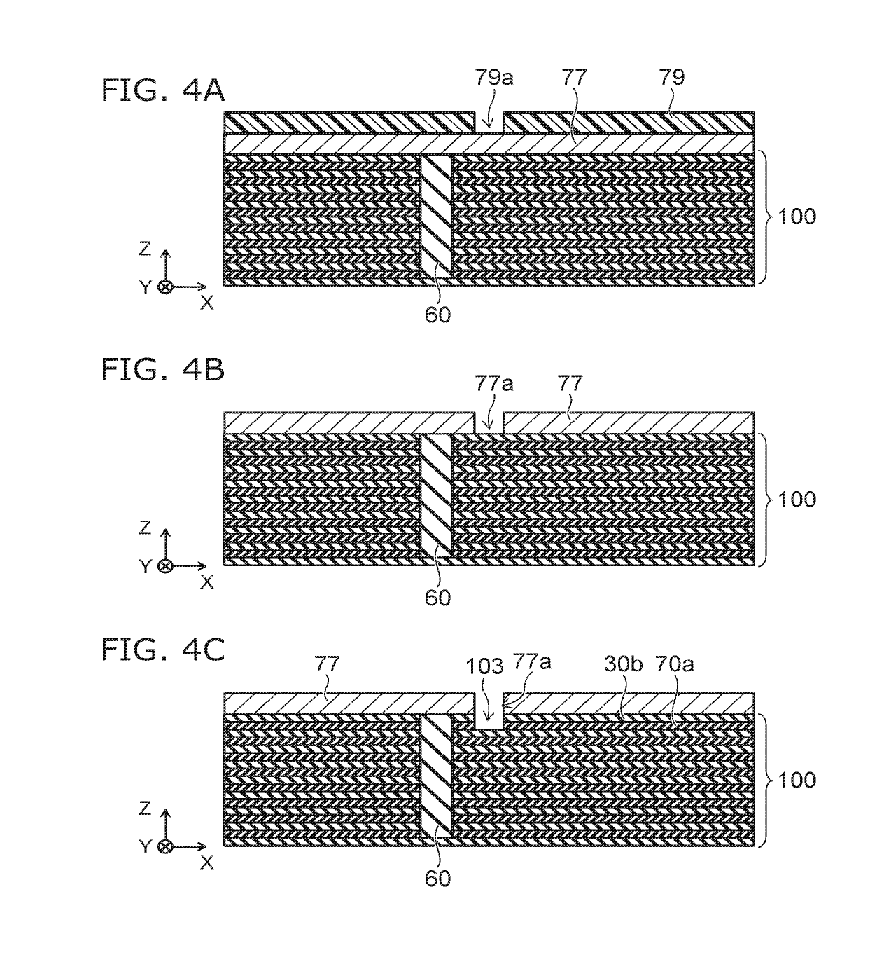

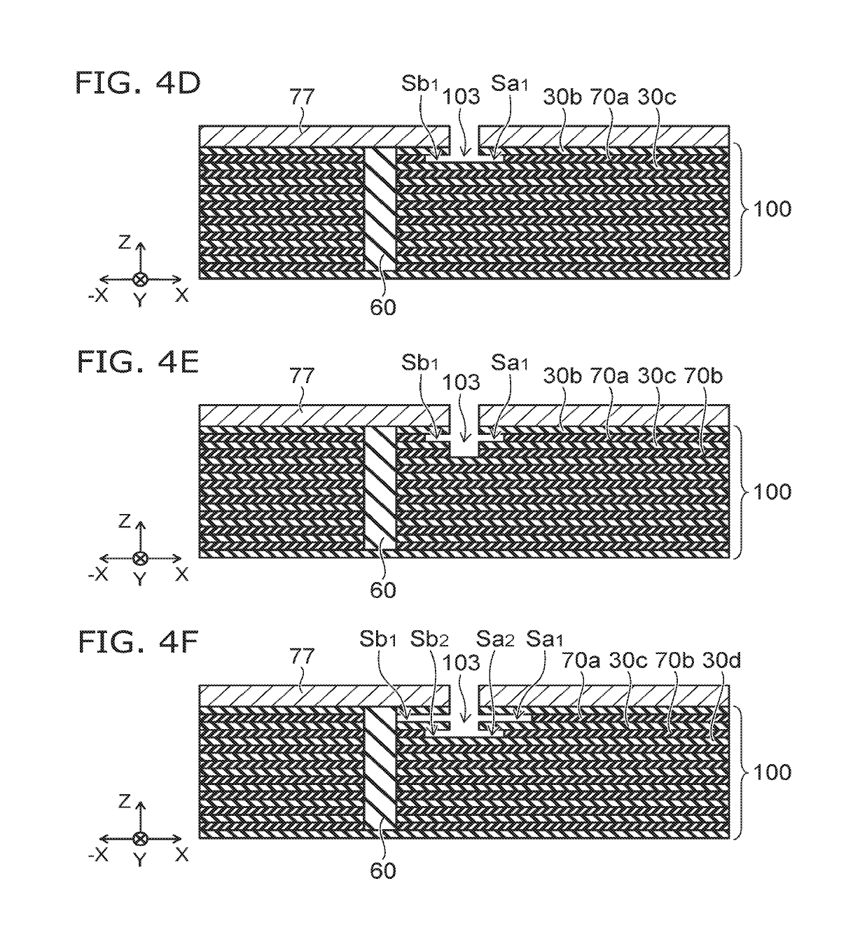

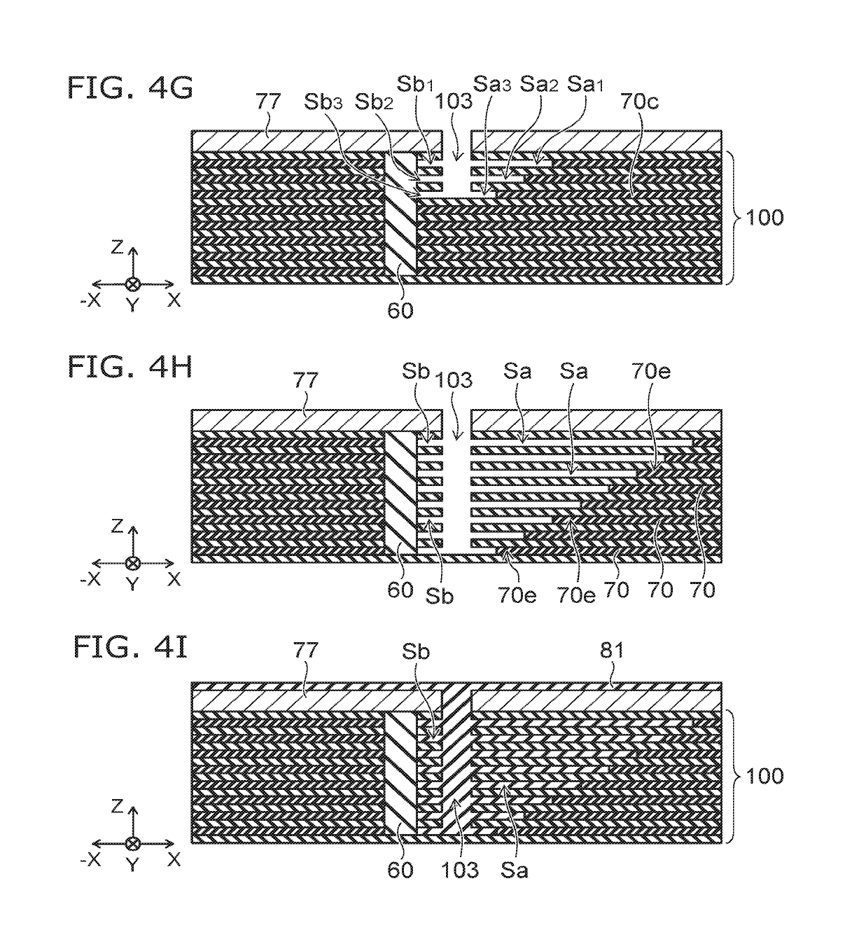

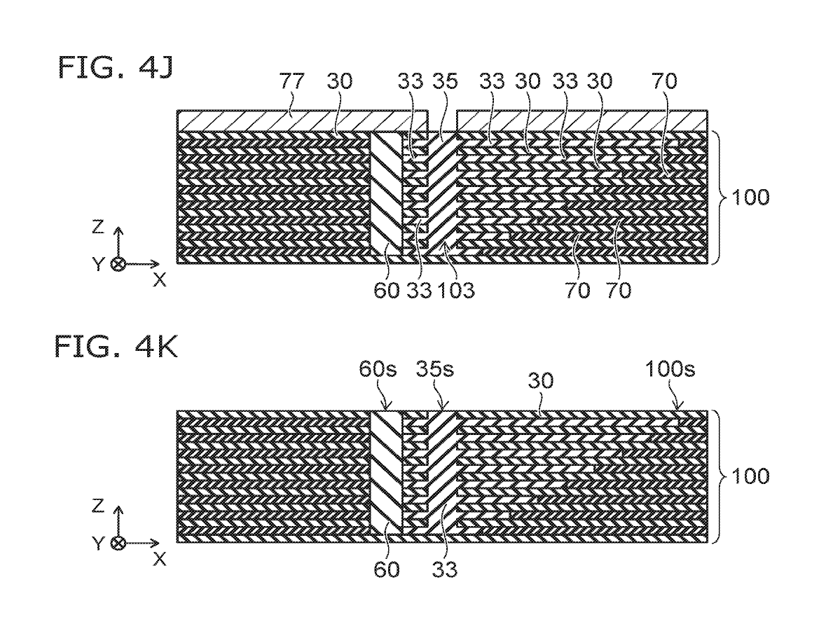

As shown in FIG. 4A, a mask layer 77 is formed on the stacked body 100. The mask layer 77 is, for example, an amorphous silicon layer. Further, a resist mask 79 is formed on the mask layer 77. The resist mask 79 has an opening 79a.

As shown in FIG. 4B, an opening 77a is formed in the mask layer 77. The opening 77a is formed by the selective etching using the resist mask 79.

As shown in FIG. 4C, a trench 103 is formed in the staked body 100. The trench 103 is provided at a position close to the barrier body 60 in the X-direction. The trench 103 extends in the Y-direction and the −Y-direction. The trench 103 is formed by the selective etching of the insulating layer 30b and the sacrificial layer 70a via the opening 77a of the mask layer 77. The insulating layer 30b and the sacrificial layer 70a are removed, for example, by anisotropic RIE.

As shown in FIG. 4D, spaces Sa1 and Sb1 are formed between the insulating layers 30b and 30c by the selective etching of the sacrificial layer 70a through the trench 103. The space Sa1 extends in the X-direction from the trench 103. The space Sa2 extends in the −X-direction from the trench 103. The spaces Sa1 and Sb1 are formed, for example, using an isotropic dry etching such as chemical dry etching (CDE).

As shown in FIG. 4E, the insulating layer 30c and the sacrificial layer 70b are selectively removed to extend the trench 103 downward. The insulating layer 30c and the sacrificial layer 70b are removed, for example, by anisotropic RIE.

As shown in FIG. 4F, spaces Sa2 and Sb2 are formed between the insulating layers 30c and 30d by the selective etching of the sacrificial layer 70b via the trench 103. The sacrificial layer 70a is also removed simultaneously by the etching. Thus, the spaces Sa1 and Sb1 are expanded respectively in the X-direction and the −X-direction. These etching processes are implemented using CDE, for example. When the space Sb1 reaches the barrier body 60, no further expand of the space Sb1 is obtained.

As shown in FIG. 4G, the trench 103 is further extended downward to form spaces Sa3 and Sb3. The spaces Sa3 and Sb3 are formed by the selective etching of the sacrificial layer 70c. The spaces Sa1 and Sa2 are simultaneously expanded in the X-direction by the etching. The spaces Sb1, Sb2, and Sb3 are formed to have widths from the trench 103 to the barrier body 60.

As shown in FIG. 4H, the trench 103 is extended downward to the depth reaching the lowermost sacrificial layer 70e. Spaces Sa and Sb are formed between the insulating layers 30 by the selective etching of the sacrificial layers 70. As a result, the end parts 70e of the sacrificial layers 70 are formed into stairs. The extension of the space Sb in the −X-direction from the trench 103 is restricted by the barrier body 60. In this specification, there is the case in which the spaces are individually denoted as Sa1, Sa2 and Sa3, and the other cases in which the spaces are collectively denoted as space Sa, for convenience. These manners are also applied to the other elements.

The trench 103 also extends in the Y-direction and the −Y-direction and may join to the barrier body 60 (see FIG. 3B). Thus, the space formed by the etching of the sacrificial layer 70 is formed not to extend over the barrier body 60 in the Y-direction and the −Y-direction. Thus, each of the contact regions CA1 to CA4 shown in FIG. 3B is not expanded over the barrier body 60 in the Y-direction and the −Y-direction. Thereby, the contact regions CA1-CA4 are formed with a smaller area than that in the case without forming the barrier body 60.

As shown in FIG. 4I, an insulating layer 81 is formed on the mask layer 77 and embedded in the trench 103 and the spaces Sa and Sb. The insulating layer 81 is a silicon oxide layer formed by LPCVD, for example.

As shown in FIG. 4J, the portions of the insulating layer 81 deposited on the upper surface of the mask layer 77 and above the trench 103 are removed, for example, by dry etching. Hereinafter, the portions of the insulating layer 81 embedded in the spaces Sa and Sb are referred to as insulating layers 33.

The portion of the insulating layer 81 embedded in the trench 103 is referred to as insulating layer 35.

The insulating layers 33 and 35 are silicon oxide layers formed by LPCVD, for example. In contrast, the insulating layer 30 is a silicon oxide layer formed by PCVD. Thus, the insulating layer 30 may contains hydrogen atoms with a higher density than a hydrogen atom density in the insulating layers 33 and 35. That is, the silicon oxide layer formed by PCVD contains hydrogen atoms, which terminate the dangling bonds of silicon atoms, more than the hydrogen atoms in the silicon oxide layer formed by LPCVD. Thus, the etching rate using buffered hydrofluoric acid is larger in the insulating layer 30 than that in the insulating layers 33 and 35.

As shown in FIG. 4K, the mask layer 77 is removed. The mask layer 77 is selectively removed, for example, using an alkali-based etching liquid. The insulating layer 35 may be formed such that the upper surface 35s thereof is located at the same level as the top surface of the uppermost insulating layer 30. Thus, the upper surface 100s of the stacked body 100 is planarized, and the planarized surface may facilitate the manufacturing process of forming fine interconnects thereon.

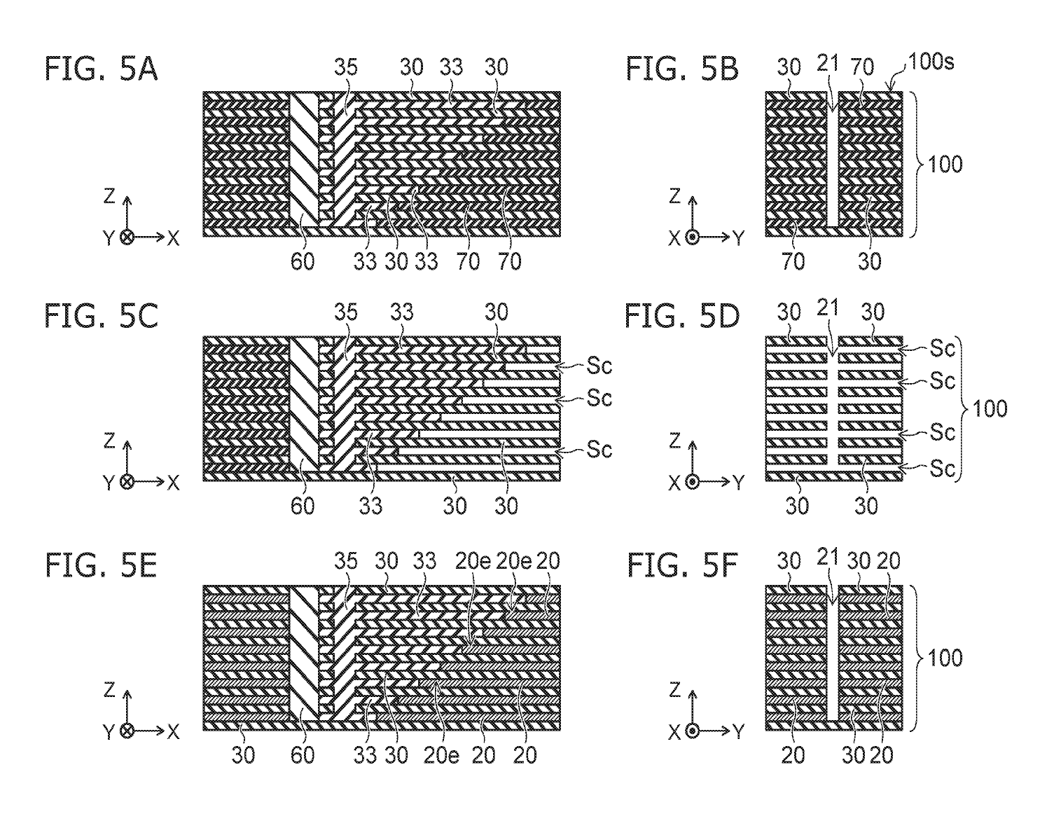

FIG. 5A is a schematic view showing the X-Z cross section of the stacked body 100 in which the insulating layers 33 and 35 are formed. FIG. 5B is a schematic view showing the Y-Z cross section thereof. As shown in FIG. 5B, a slit 21 is formed in the stacked body 100. The slit 21 is provided in the memory region MA (see FIG. 3B). The slit 21 has a depth reaching the lowermost sacrificial layer 70 from the upper surface 100s of the stacked body 100. The slit 21 also extends in the X-direction and divides the sacrificial layers 70.

As shown in FIGS. 5C and 5D, the sacrificial layers 70 are selectively removed through the slit 21 to form a space Sc between the adjacent insulating layers 30. The sacrificial layers 70 are removed, for example, by the wet etching using phosphoric acid.

As shown in FIGS. 5E and 5F, a word line 20 is formed in the space Sc through the slit 21. The word line 20 is, for example, a metal layer formed using CVD. The word line 20 is, for example, a tungsten layer. Thus, the sacrificial layers 70 are replaced with the word lines 20, and the end parts 20e of the word lines 20 stacked in the Z-direction are formed into stairs on the barrier body 60 side.

The above embodiment shows an example in which the insulating layers 30, 33, and 35 are silicon oxide layers and the sacrificial layer 70 is a silicon nitride layer. However, the embodiment is not limited thereto. For instance, the sacrificial layer 70 may be a polysilicon layer. Further, a metal oxide layer may be used in the stacked body 100 instead of the silicon oxide layer.

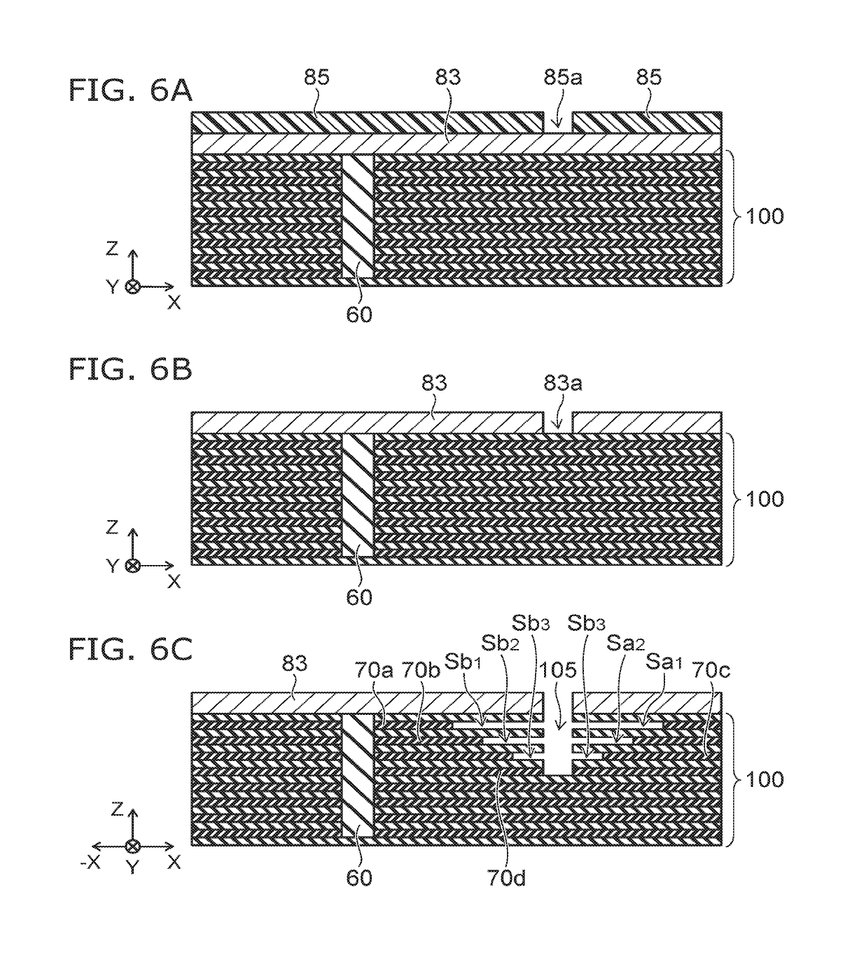

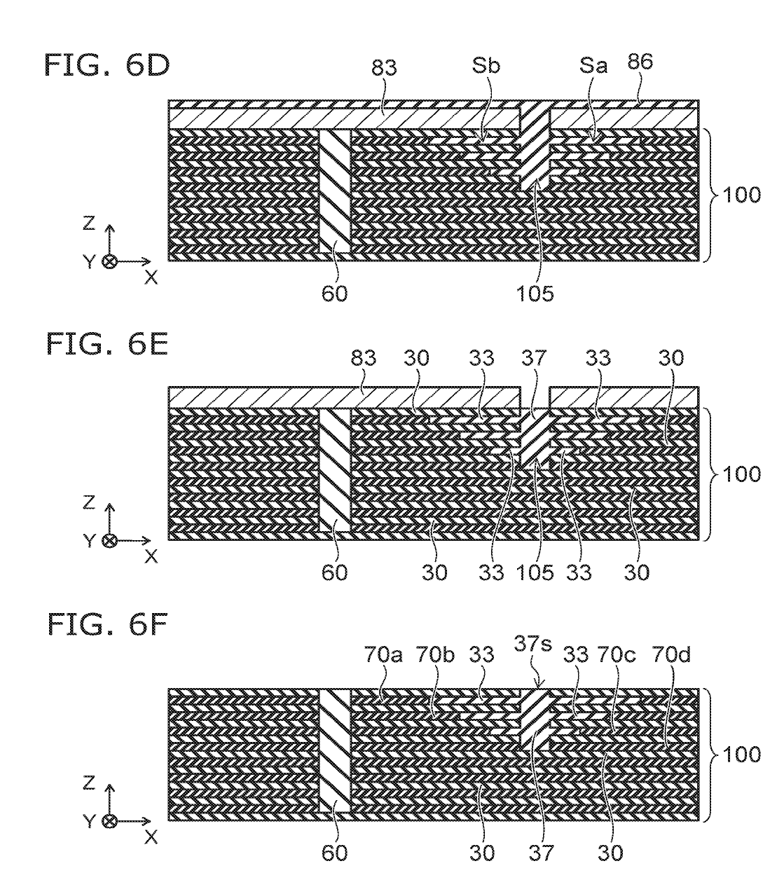

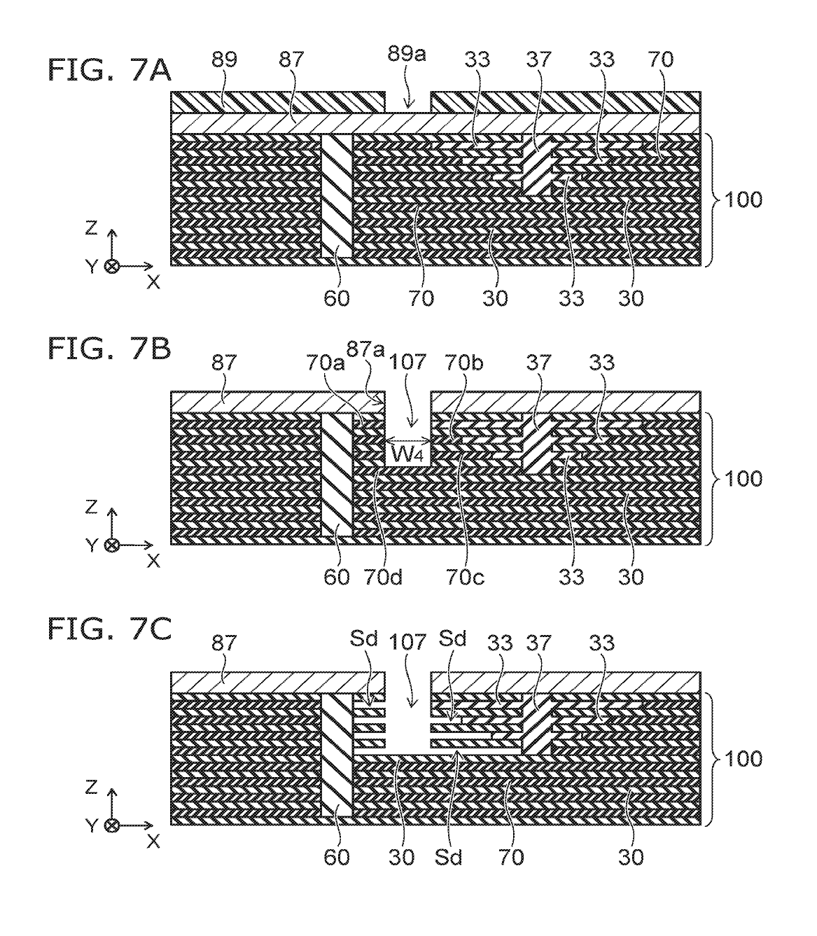

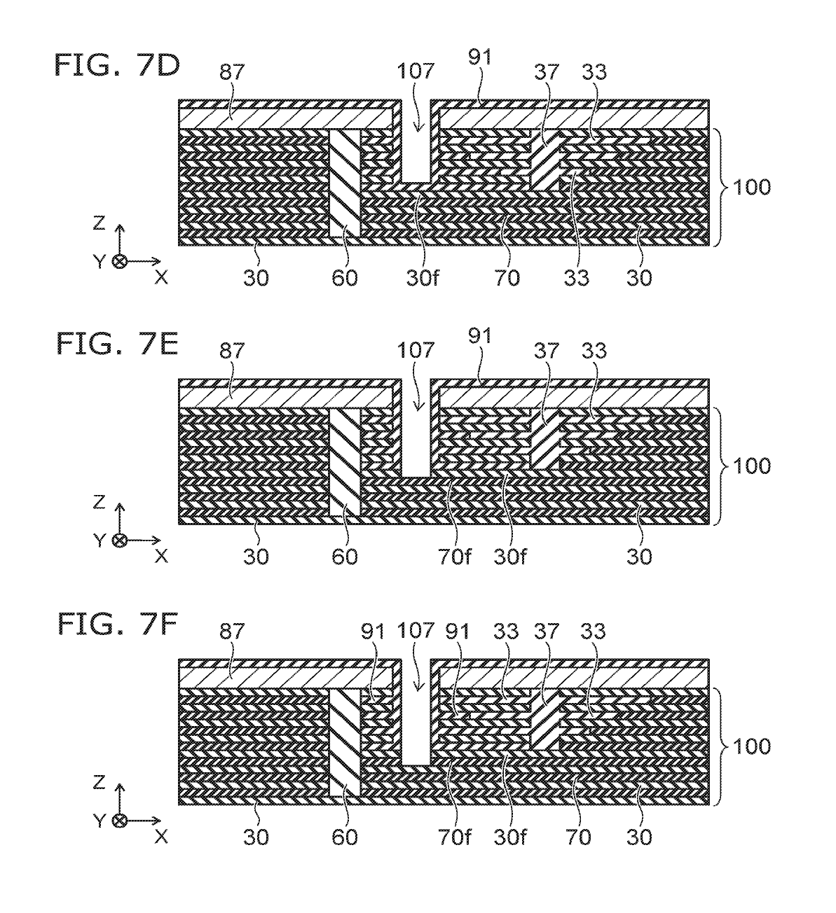

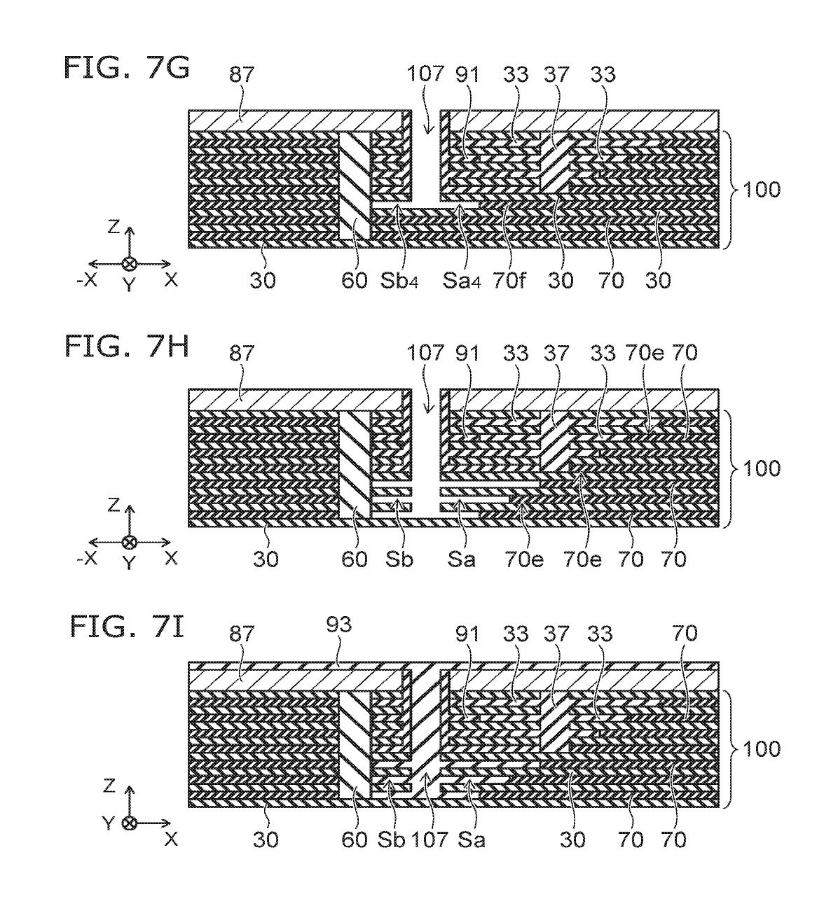

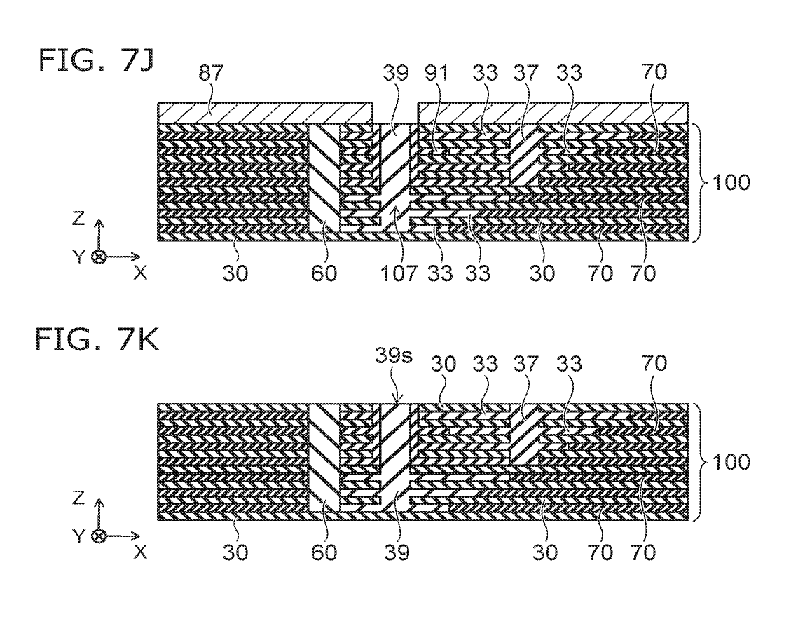

Next, a method for manufacturing the non-volatile memory device 1 according to a variation of the embodiment is described with reference to FIGS. 6A to 7K. FIGS. 6A to 7K are schematic sectional views sequentially showing the process for manufacturing the non-volatile memory device 1 according to the variation of the embodiment.

As shown in FIG. 6A, a mask layer 83 is formed on the stacked body 100. The mask layer 83 is, for example, an amorphous silicon layer. Furthermore, a resist mask 85 is formed on the mask layer 83. The resist mask 85 has an opening 85a. The stacked body 100 includes a barrier body 60.

As shown in FIG. 6B, an opening 83a is formed in the mask layer 83. The opening 83a is formed by etching the mask layer 83 using the resist mask 85.

As shown in FIG. 6C, a trench 105 is formed by selectively removing the insulating layers 30 and the sacrificial layers 70 through the opening 83a. Furthermore, the sacrificial layers 70a, 70b and 70c are removed through the trench 105 to form spaces Sa1, Sa2, Sa3 and spaces Sb1, Sb2, Sb3. This procedure is, for example, the same as the method shown in FIGS. 4C to 4G.

The trench 105 is formed at a position farther from the barrier body 60 than the trench 103 shown in FIG. 4C. The trench 105 extends in the Y-direction and the −Y-direction. Thus, the spaces Sb1, Sb2 and Sb3 are expanded in the −X-direction without being blocked by the barrier body 60. The trench 105 has a depth reaching the sacrificial layer 70d lower than the sacrificial layer 70c.

As shown in FIG. 6D, an insulating layer 86 is formed to be embedded in the trench 105 and the spaces Sa and Sb. The insulating layer 86 is, for example, a silicon oxide layer formed by LPCVD.

As shown in FIG. 6E, the insulating layer 86 is etched back, for example, by dry etching to remove a portion deposited on the upper surface of the mask layer 83 and a portion deposited above the trench 105. Hereinafter, the portions embedded in the spaces Sa and Sb are referred to as insulating layers 33. The portion embedded in the trench 105 is referred to as insulating layer 37.

As shown in FIG. 6F, the mask layer 83 is removed. The mask layer 83 is selectively removed, for example, using an alkali-based etching liquid. The insulating layer 37 is formed such that the upper surface 37s thereof is located at the same level as the top surface of the uppermost insulating layer 30.

As shown in FIG. 7A, a mask layer 87 is formed on the stacked body 100. The mask layer 87 is, for example, an amorphous silicon layer. Further, a resist mask 89 is formed on the mask layer 87. The resist mask 89 has an opening 89a.

As shown in FIG. 7B, a trench 107 is formed in the stacked body 100. The trench 107 is formed by selectively removing the insulating layers 30 and the sacrificial layers 70 through the opening 87a of the mask layer 87. The opening 87a is formed by selectively removing the mask layer 87 through the opening 89a of the resist mask 89. The trench 107 is formed by selectively removing the insulating layers 30 and the sacrificial layers 70 using anisotropic RIE, for example.

The trench 107 is formed between the trench 105 shown in FIG. 6C and the barrier body 60. The trench 107 extends in the Y-direction and the −Y-direction. The width W₄ of the trench 107 in the X-direction is wider than the width of the trench 105 in the X-direction. The trench 107 has a depth reaching the sacrificial layer 70d.

As shown in FIG. 7C, a space Sd is formed between the adjacent insulating layers 30. The space Sd is formed by selectively removing the sacrificial layers 70a, 70b, 70c, and 70d through the trench 107. The sacrificial layers 70a, 70b, 70c, and 70d shown in FIG. 7B are selectively removed, for example, by wet etching using phosphoric acid.

As shown in FIG. 7D, an insulating layer 91 is formed on the mask layer 87. Further, the insulating layer 91 also covers the inner surface of the trench 107, and parts of the insulating layer 91 are embedded in the spaces Sd. The insulating layer 91 is, for example, a silicon oxide layer formed by LPCVD. For example, the parts of the insulating layer 91 join the insulating layers 33 between the insulating layer 37 and the barrier body 60.

As shown in FIG. 7E, a portion of the insulating layer 91 deposited on the bottom surface of the trench 107 and a part of the insulating layer 30f are selectively removed. The portion of the insulating layer 91 and the part of the insulating layer 30f are removed, for example, using anisotropic RIE.

As shown in FIG. 7F, the sacrificial layer 70f exposed at the bottom surface of the trench 107 is further removed by the etching using anisotropic RIE, for example. A portion of the insulating layer 91 deposited on the upper surface of the mask layer 87 is also removed while removing the portion on the bottom surface of the trench 107, the part of the insulating layer 30f and a part of the sacrificial layer 70f.

As shown in FIG. 7G, the sacrificial layer 70f is etched through the trench 107 to form spaces Sa4 and Sb4 between the insulating layers 30. The spaces Sa4 and Sb4 extend from the trench 107 in the X-direction and the −X-direction, respectively. The sacrificial layer 70f is selectively removed, for example, using CDE.

As shown in FIG. 7H, the trench 107 is extended to a depth reaching the lowermost sacrificial layer 70. The sacrificial layer 70 is removed to form spaces Sa and Sb. For example, an anisotropic etching of an insulating layer 30 and a sacrificial layer 70 using RIE, and an isotropic etching of a sacrificial layer 70 using CDE are alternately repeated in this process. As a result, the ends of the sacrificial layers 70 on the barrier body side are formed into stairs.

As shown in FIG. 7I, an insulating layer 93 is formed on the mask layer 87. Parts of the insulating layer 93 are embedded in the trench 107 and the spaces Sa and Sb. The insulating layer 93 is, for example, a silicon oxide layer formed by LPCVD.

As shown in FIG. 7J, the insulating layer 93 is etched back, for example, by dry etching to remove a portion deposited on the upper surface of the mask layer 87 and a portion deposited above the trench 107. Hereinafter, the portions embedded in the spaces Sa and Sb are referred to as insulating layers 33. The portion embedded in the trench 107 is referred to as an insulating layer 39.

As shown in FIG. 7K, the mask layer 87 is removed. The mask layer 87 is selectively removed, for example, using an alkali-based etching liquid. The insulating layer 39 is formed such that the upper surface 39s thereof is located at the same level as the top surface of the uppermost insulating layer 30. Furthermore, the word lines 20 are formed by replacing the sacrificial layers 70 with metal layers. For example, the sacrificial layers 70 are replaced with tungsten layers according to the procedure shown in FIGS. 5A to 5F. In the example, the end positions of the insulating layers 33 may be precisely controlled in the X-direction by forming the trenches 105 and 107 in the stacked body 100. That is, it becomes possible to suppress variations of etching amounts of the sacrificial layers 70, which are enlarged as the width of the space Sa in the X-direction becomes wider.

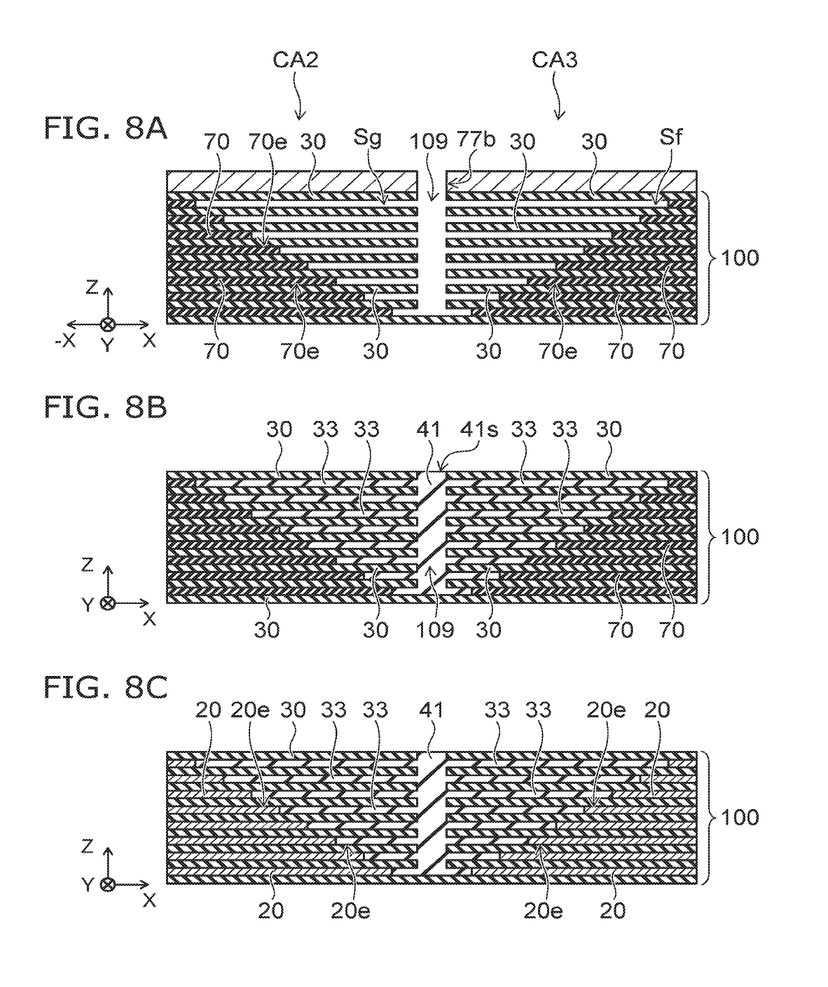

FIGS. 8A to 8C are schematic sectional views showing a process for manufacturing the non-volatile memory device 1 according to another variation of the embodiment. The end stairs of the word lines 20 are formed on both sides of the trench 109 in this example. Such a structure is advantageous, for example, in the case where the barrier body 60 surrounds the memory blocks MB1 and MB2 shown in FIG. 3B without the parts that divide the space between the memory blocks MB1 and MB2 into the contact regions C2 and C3. A procedure for forming the end stairs is the same as the process shown in FIGS. 4A to 5F.

In this case, a trench 109 separating the contact region C2 and the contact region C3 is formed as shown in FIG. 8A. The trench 109 extends in the Y-direction and the −Y-direction. Further, the sacrificial layers 70 are removed through the trench 109 to form spaces Sf and Sg. At the same time, the trench 103 and the spaces Sa and Sb shown in FIG. 4H are formed in the contact regions C1 and C4 (not shown). The spaces Sf and Sg extend evenly from the trench 109 in the X-direction and the −X-direction respectively. Thus, the end parts 70e of the sacrificial layers 70 are formed into stairs on both sides of the trench 109.

As shown in FIG. 8B, an insulating layer 33 is embedded in the spaces Sf and Sg through the trench 109. An insulating layer 41 is embedded in the trench 109. The insulating layer 41 is formed such that the upper surface 41s thereof is located at the same level as the top surface of the uppermost insulating layer 30. The insulating layer 41 separates the contact region CA2 and the contact region CA3.

As shown in FIG. 8C, the word lines 20 are formed, for example, by replacing the sacrificial layers 70 with tungsten layers. This process is implemented according to the steps shown in FIGS. 5A to 5F. The sacrificial layer 70 is selectively removed through a slit 21, not shown (see FIG. 5C). The word line 20 is formed, for example, using CVD. Thus, the word lines 20 on both sides of the insulating layer 41 are formed so as to have stairs at the end parts 20e extending from the adjacent memory blocks MB.

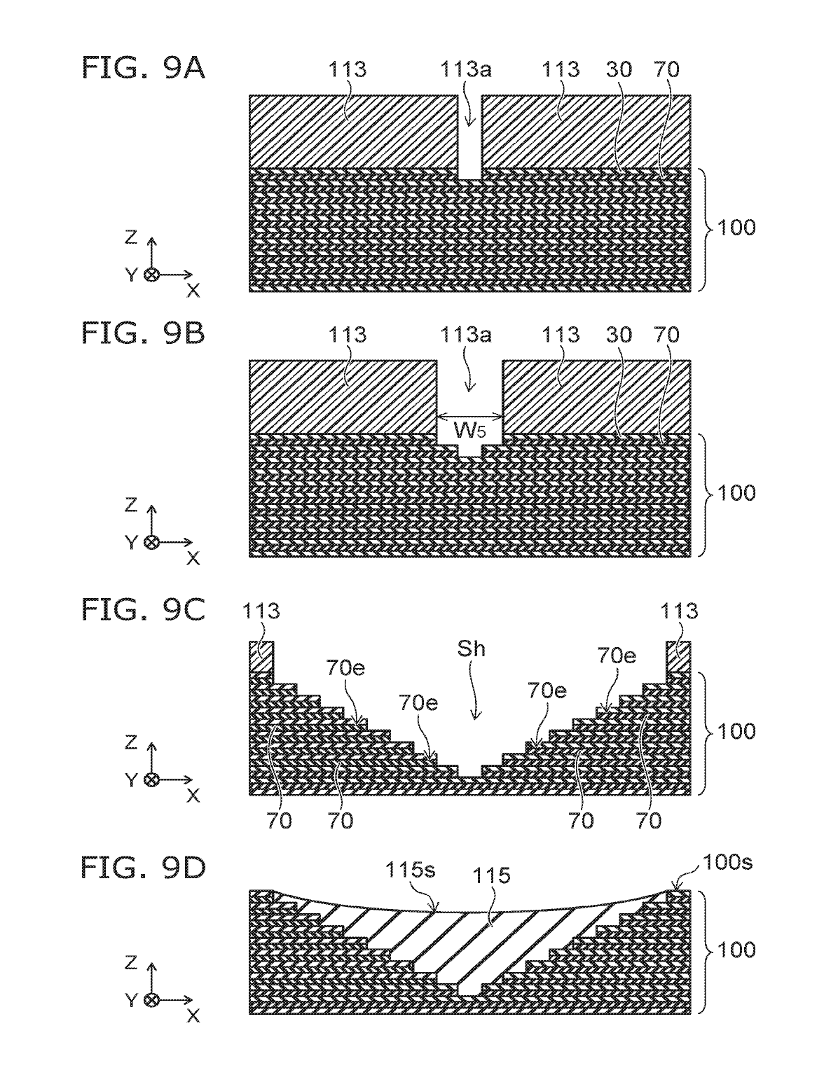

Next, a method for manufacturing the non-volatile memory device according to a comparative example is described with reference to FIGS. 9A to 9D. FIGS. 9A to 9D are schematic sectional views sequentially showing the process for manufacturing the non-volatile memory device according to the comparative example.

As shown in FIG. 9A, a resist mask 113 is formed on the stacked body 100. The resist mask 113 has an opening 113a. The insulating layer 30 and the sacrificial layer 70 exposed at the bottom surface of the opening 113a are sequentially removed, for example, by the etching using anisotropic RIE.

As shown in FIG. 9B, the opening 113a is expanded to have a width W5 in the X-direction by etching the resist mask 113. Then, the insulating layer 30 and the sacrificial layer 70 exposed at the bottom surface of the opening 113a are sequentially removed. The stairs shown in FIG. 9C are formed by further repeating etching of the resist mask 113 and removal of the insulating layer 30 and the sacrificial layer 70 exposed at the bottom surface of the opening 113a. In this example, the stairs are not limited to be formed in the X-direction. Other stairs, not shown, may also be formed in the Y-direction.

As shown in FIG. 9D, an insulating layer 115 is formed to cover the stairs, and the upper surface 100s of the stacked body 100 is planarized using CMP. The insulating layer 115 is, for example, a silicon oxide layer. More specifically, a silicon oxide layer is formed using CVD on the stacked body 100 after the stairs are formed therein. Then, the silicon oxide layer is polished by CMP in order to planarize the surface of the stacked body 100. In this case, a space Sh above the stairs has a wide opening. Thus, it is difficult to achieve the insulating layer 115 having completely planarized upper surface 115s, since a depression is formed in the upper surface 115s due to the dishing effect of CMP.

In contrast, as shown in FIG. 4J, for example, the insulating layer 30 remains above each stairs, and the insulating layer 33 is formed therebetween. Thus, the wide space Sh is not formed above the stairs in the embodiment. Accordingly, the surface of the stacked body 100 is maintained to be flatter. This makes it possible to achieve high resolution in the photolithography process for forming a gate interconnect 23 and a bit line 15 on the stacked body 100, and provides the fine interconnects thereon.

Further, the etching process of the resist mask is not applied in the embodiment. Thus, it becomes possible to use a thin photoresist, and an exposure apparatus, for example, using a KrF excimer laser as a light source, or an exposure apparatus with a still higher resolution. As a result, the end stairs according to the embodiment may have narrower width in the X-direction, and reduce the area of the contact regions CA1, CA2, CA3 and CA4.

Furthermore, in the embodiment, the etching of the sacrificial layer 70 is blocked in the Y-direction by the barrier body 60. Thus, it may be possible to restrict the stairs formed only in the X-direction in the contact region, and provide the contact region with the smaller area than that in the comparative example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a first electrode;
a second electrode stacked on the first electrode;
a semiconductor layer extending in a first direction through the first electrode and the second electrode;
charge storage parts respectively provided between the first electrode and the semiconductor layer and between the second electrode and the semiconductor layer; and
a barrier body arranged with the first electrode and the second electrode in a second direction orthogonal to the first direction and extending in the first direction,
a distance between the second electrode and the barrier body being wider in the second direction than a distance between the first electrode and the barrier body.

2. The device according to claim 1, further comprising:
a first insulating layer provided between the first electrode and the barrier body and extending in the second direction;
a second insulating layer provided between the second electrode and the barrier body and extending in the second direction;
a third insulating layer provided between the first insulating layer and the second insulating layer and extending in the second direction; and
a conductor electrically connected to the first electrode,
wherein the third insulating layer covers a surface of the first electrode on the second electrode side, and
the conductor extends through the second insulating layer and the third insulating layer and is in contact with the first electrode.

3. The device according to claim 2, wherein
the first electrode has an end in contact with the first insulating layer,
the second electrode has an end in contact with the second insulating layer, and
the third insulating layer extends between the first electrode and the second electrode.

4. The device according to claim 2, wherein
the first insulating layer and the second insulating layer each contain hydrogen atoms with a lower density than a density of hydrogen atoms in the third insulating layer.

5. The device according to claim 4, wherein
the barrier body is an insulator containing silicon, and contains hydrogen atoms with a higher density than the density of hydrogen atoms in the first insulating layer and the second insulating layer.

6. The device according to claim 4, wherein
the barrier body is an insulator containing silicon, and contains hydrogen atoms with a lower density than the density of hydrogen atoms in the third insulating layer.

7. The device according to claim 2, wherein the first insulating layer, the second insulating layer, and the third insulating layer are silicon oxide layers.

8. The device according to claim 1, wherein the barrier body includes silicon oxide.

9. The device according to claim 1, wherein the barrier body is provided to surround the first electrode and the semiconductor layer in a plane orthogonal to the first direction.

10. The device according to claim 1, further comprising:
a third electrode stacked on the second electrode in the first direction,
wherein a distance between the barrier body and the third electrode is wider than the distance between the barrier body and the second electrode.

11. The device according to claim 2, further comprising:
an interconnect layer including a first interconnect electrically connected to the semiconductor layer and a second interconnect electrically connected to the first electrode through the conductor,
wherein the second electrode is located between the first electrode and the interconnect layer.

12. A method for manufacturing a non-volatile memory device, comprising:
forming a stacked body including first insulating layers stacked in a first direction and layers each provided between adjacent first insulating layers in a first direction, the layers including a first layer and a second layer located at a lower level in the first direction than the first layer, and one of the first insulating layers being provided between the first layer and the second layer;
forming a first trench having a depth reaching the first layer from an upper surface of the stacked body;
selectively removing a first part of the first layer though the first trench to form a first space;
extending the first trench downward through the one of the first insulating layer to a depth reaching the second layer;
selectively removing a second part of the first layer and a part of the second layer through the first trench, the first space being expanded by removing the second part of the first layer and a second space being formed by removing the part of the second layer; and
forming a second insulating layer in the first space and the second space.

13. The method according to claim 12, wherein
the first space and the second space extend in a second direction orthogonal to the first direction, and
the first space has a length in the second direction longer than a length of the second space in the second direction.

14. The method according to claim 12, further comprising:
forming a second trench close to the first trench in a second direction orthogonal to the first direction, the second trench having a depth deeper than the first trench; and
embedding a third insulating layer inside the second trench,
wherein the third insulating layer blocks the first space and the second space expanding thereto.

15. The method according to claim 14, wherein
the first trench extends in a third direction orthogonal to the first direction and the second direction,
the second trench is formed to surround the first trench and a part of the stacked body in a plane orthogonal to the first direction, and
the third insulating layer blocks the first space and the second space expanding in the third direction.

16. The method according to claim 14, further comprising:
forming a third trench having a depth reaching the second layer between the first trench and the second trench;
selectively removing the first layer and the second layer between the first trench and the second trench through the third trench;
extending the third trench downward to a depth reaching a third layer located at a level lower than the second layer in the first direction and etching the third layer;
selectively removing a part of the third layer through the third trench to form a third space; and
forming a fourth insulating layer in the third space.

17. The method according to claim 16, wherein
the third space has an end on the first trench side; and
a distance between the second trench and the end of the third space in the second direction is shorter than a distance between the first trench and the second trench.

18. The method according to claim 12, further comprising:
forming a slit dividing the first layer and the second layer after forming the second insulating layer; and
replacing the first layer and the second layer by a metal layer through the slit.

19. The method according to claim 18, wherein the slit extends in the first direction and the second direction.

20. A non-volatile memory device comprising:
an underlying layer;
a memory block provided on the underlying layer, the memory block including:
a plurality of word lines stacked in a first direction perpendicular to a top surface of the underlying layer, the plurality of word lines extending in a second direction along the top surface of the underlying layer, and
a semiconductor layer extending in the first direction through the plurality of word lines; and
a barrier body surrounding the memory block on the underlying layer,
the plurality of word lines having ends formed into stairs in the second direction, and not having portions formed into stairs in a third direction crossing the second direction on the underlying layer.
